(19) United States
(12) Patent Application Publication
(10) Pub. No.: US 2025/0216797 A1
(43) Pub. Date: Jul. 3, 2025

(54) OPTICAL ELEMENT FOR A PROJECTION EXPOSURE SYSTEM, OPTICAL SYSTEM COMPRISING SAME AND PROJECTION EXPOSURE SYSTEM COMPRISING THE OPTICAL ELEMENT AND/OR THE OPTICAL SYSTEM

(71) Applicant: Carl Zeiss SMT GmbH, Oberkochen (DE)

(72) Inventors: Sonia Anaelle BISSIE, Aalen (DE); Wolfgang SCHERM, Nattheim (DE); Tobias FUSENIG, Aachen (DE); Daniel PAETZ, Erfurt (DE); Marwene NEFZI, Aalen (DE); Jens PROCHNAU, Oberkochen (DE); Jens KUGLER, Aalen (DE); Matthias FETZER, Stuttgart (DE)

(21) Appl. No.: 19/082,944

(22) Filed: Mar. 18, 2025

Related U.S. Application Data
(63) Continuation of application No. PCT/EP2023/074291, filed on Sep. 5, 2023.

(30) Foreign Application Priority Data
Sep. 27, 2022 (DE) 10 2022 210 171.5

(51) Int. Cl. G03F 7/00

(52) U.S. Cl. CPC G03F 7/70316; G03F 7/70233; G03F 7/70266

(57) ABSTRACT

An optical element for a projection exposure system. The optical element comprises a mirror body having a mirror section with an optically active surface and a base section provided on the rear side of the mirror section. The base section has a greater stiffness than the mirror section. The optical element also comprises multiple actuator connectors for connecting actuators to the optical element. The actuator connectors are provided on the base section. The optical element further comprises a stiffening rib structure attached on the rear side of the mirror section.

### CROSS-REFERENCE TO RELATED APPLICATIONS

The present application is a continuation of, and claims benefit under 35 USC 120 to, international application No. PCT/EP2023/074291, filed Sep. 5, 2023, which claims benefit under 35 USC 119 of German Application No. 10 2022 210 171.5, filed Sep. 27, 2022. The entire disclosure of each of these applications is incorporated by reference herein.

### FIELD

The present disclosure relates to an optical element for a projection exposure apparatus, to an optical system having such an optical element, and to a projection exposure apparatus having such an optical element and/or such an optical system.

### BACKGROUND

Microlithography is used for producing microstructured components, such as integrated circuits. The microlithography process is performed using a lithography apparatus, which comprises an illumination system and a projection system. The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light at a wavelength ranging from 0.1 nm to 30 nm, such as 13.5 nm, are currently under development. In the case of such EUV lithography apparatuses, because of the high absorption of light at this wavelength by most materials, reflective optical units, which is to say mirrors, are typically used instead of—as previously—refractive optical units, which is to say lens elements.

The trend in future projection systems for the EUV range is toward high numerical apertures (NA). The expectation is therefore that the optical surfaces, and hence the mirrors, will become larger. This trend makes it more difficult to achieve high control bandwidth because the latter depends, inter alia, on the first internal natural frequency of the respective mirror body. Low natural frequencies can lead to the sensors used for the closed-loop control starting to vibrate in the low frequency range. Consequently, the rigid body closed-loop control can be already unstable at low frequencies.

It is possible to show that the first natural frequency ω of a cylindrical mirror body is proportional to a thickness d of the respective mirror and inversely proportional to the square of a radius r of the optical surface. This is due to the fact that the mass is proportional to d*r², and the stiffness is proportional to d³/r². An optically active surface with the radius r therefore involves a mirror body volume proportional to r⁴ if the first natural frequency, and hence the control bandwidth of the mirror, is not reduced. Since material costs are proportional to the substrate volume, the demand for a high control bandwidth can become ever more expensive. It would be desirable to improve this.

### SUMMARY

The present disclosure seeks to provide an improved optical element.

Accordingly, an optical element for a projection exposure apparatus is proposed. The optical element comprises a mirror body, the mirror body comprising a mirror portion with an optically active surface and a base portion provided on the back side of the mirror portion, and the base portion having a greater rigidity in comparison with the mirror portion, a plurality of actuator connectors for connecting actuators to the optical element, the actuator connectors being provided on the base portion, and a stiffening rib structure attached to the back side of the mirror portion.

As a result of the base portion having a greater stiffness in comparison with the mirror portion, the base portion may serve as a support for the actuator connectors. As a result, the mirror portion may be embodied with thinner walls in comparison with the base portion, whereby a significant weight reduction of the optical element can be achieved.

The optical element can be a mirror. The optical element can be a part of a projection optical unit of the projection exposure apparatus. For example, the mirror body may be manufactured from a ceramic material or a glass ceramic material. The optically active surface is suitable for reflecting illumination radiation, such as EUV radiation. The optically active surface is a mirror surface, for example. The optically active surface may be applied to the mirror body, for example the mirror portion, using a coating method. The optically active surface may also be referred to as the optically effective surface. The optically active surface may be curved, for example toroidally curved.

The mirror portion can be panel-shaped or slab-shaped. For example, the mirror portion can have thinner walls than the base portion. The base portion can be in the form of a block-shaped or cylindrical solid body, which can be significantly more massive in comparison with the mirror portion. As mentioned previously, the mirror portion can be panel-shaped or slab-shaped and can have a significantly lower material strength in comparison with the base portion. As a result, the mirror portion can be substantially softer or less stiff in comparison with the base portion.

The “stiffness” in the present case is quite generally understood to mean the resistance of a body to an elastic deformation due to a force or a torque. The stiffness may be influenced by the utilized geometry and the utilized material. In the present case, the mirror portion can have a thinner wall in comparison with the base portion, whereby the lower stiffness of the mirror portion arises in comparison with the base portion.

The mirror portion can have the optically active surface on the front side, for example. The mirror portion can comprise a back side facing away from the optically active surface. The base portion can be provided on the back side. The fact that the base portion is “provided” on the back side of the mirror portion in the present case means that the base portion extends from the back side of the mirror portion. The base portion thus faces away from the optically active surface.

The mirror body can be a monolithic component. In the present case, “monolithic”, “in one part” or “in one piece” means that the mirror portion, the base portion and the actuator connectors form a single component, specifically the mirror body, and are not composed of different components. Further, the mirror body may also be constructed materially in one piece. In the present case “materially in one piece” means that the mirror body is produced from the same material throughout.

In an alternative to that, the mirror body can also be a multi-part component. For example, the mirror body may in this case include a plurality of different components in the form of the base portion, the mirror portion and/or the actuator connectors. These components can be connected together to form the mirror body. From this, there is also the option of manufacturing the individual components of the mirror body from different materials. For example, materials with different coefficients of thermal expansion can be used. For example, one component of the mirror body may be manufactured from a material with a coefficient of thermal expansion of zero and at least one further component may be manufactured from an easily processible and cost-effective material, which is suitable for a light structure. For example, different ceramic materials can be used.

The optical element can have six degrees of freedom. For example, the optical element can have three translational degrees of freedom in an x-direction, a y-direction and a z-direction. In addition, the optical element can have three rotational degrees of freedom, respectively about the x-direction, the y-direction and the z-direction. In the present case, a “position” of the optical element should be understood to mean its coordinates or the coordinates of a measurement point provided on the optical element with respect to the x-direction, the y-direction and the z-direction. In the present case, an “orientation” of the optical element should be understood to mean its tilt or the tilt of the measurement point about the x-direction, the y-direction and the z-direction. In the present case, a “pose” of the optical element should be understood to mean both the position and the orientation of the optical element. Accordingly, the term “pose” may be replaced by the wording “position and orientation”.

The pose of the optical element can be influenced or adjusted with the aid of the actuators coupled to the actuator connectors. For example, the optical element may be moved from an actual pose into a target pose. Accordingly, “adjusting” or “aligning” the optical element may be understood to mean moving the optical element from its actual pose to its target pose. For example, what are known as Lorentz actuators can be used as actuators or actuating elements and are coupled to the actuator connectors. For example, what is known as an actuator-sensor unit may be used as an actuator.

In the present case, the fact that the actuator connectors are “provided” on the base portion means that, in particular, the actuator connectors are securely connected to the base portion. In this context, the actuator connectors may be part of the base portion. For example, the actuator connectors may also be formed in one piece, such as from one piece of material, with the base portion. The actuator connectors can extend out of the base portion on its back side. Optionally, exactly three actuator connectors are provided and accordingly three actuators as well. For example, the actuator connectors are arranged in a triangular fashion. Accordingly, the actuator connectors may be offset from one another by 120°.

The optical element furthermore comprises a stiffening rib structure attached to the back side of the mirror portion.

The rib structure can be part of the mirror body. In particular, this means that the rib structure may be formed in one piece, in particular from one piece of material, with the mirror body. However, this is not mandatory. The rib structure can be provided on the back side of the mirror portion. Hence, the rib structure extends from the back side of the mirror portion for example. With the aid of the rib structure, it is possible to stiffen the mirror portion at least in sections and at the same time obtain a low weight of the optical element.

According to an embodiment, the rib structure has a truss-like or honeycomb-like geometry.

In particular, this means that the rib structure may have a plurality of different ribs or rib portions which merge into one another, intersect one another or are connected to one another, and consequently form truss-shaped or honeycomb-shaped regions. In this context, the rib structure may have any desired geometric shape.

According to an embodiment, the rib structure supports the mirror portion on the base portion.

For example, this means that the rib structure connects the mirror portion to the base portion. Forces introduced into the mirror portion may be introduced into the solid base portion via the rib structure.

According to an embodiment, the rib structure comprises a circumferential rib that extends around the base portion at least in sections and a plurality of connecting ribs that connect the base portion to the circumferential rib.

The circumferential rib may be curved, such as circular arc-shaped, at least in sections. The circumferential rib may extend completely around the base portion. In an alternative to that, the circumferential rib may extend around the base portion only in part. In the latter case, the circumferential rib may begin and end on the base portion. In a plan view, the circumferential rib may be oval or elliptical. The connecting ribs and the circumferential rib can be formed in one piece, such as from one piece of material. The connecting ribs may extend away from the base portion in a star shape and in the direction of the circumferential rib that extends around the base portion. The connecting ribs intersect the circumferential rib in the process. The connecting ribs may extend through the circumferential ribs. In particular, this means that the connecting ribs do not end at the circumferential rib but extend beyond the outer side of the circumferential rib at this outer side that faces away from the base portion.

According to an embodiment, the actuator connectors are mechanically decoupled from the base portion with the aid of decoupling points.

Such a decoupling point may be assigned to each actuator connector. In an alternative, a respective decoupling point of this type may be assigned to only some of the actuator connectors. This means that actuator connectors, or at least one actuator connector, without a decoupling point may also be provided. The decoupling points can be formed as gaps or cutouts that are provided between the actuator connectors and the base portion. However, the decoupling points do not completely separate the actuator connectors from the base portion in this context, and so the actuator connectors are connected to the base portion by way of at least a certain material cross section. In the present case, “mechanical decoupling” should be understood to mean that, in particular, the decoupling points prevent unwanted forces from being transferred from the actuator connectors to the optically active surface. The actuator connectors can be cylindrical and extend out of the base portion. The decoupling points are then provided between the actuator connectors and the base portion.

According to an embodiment, the actuator connectors are connected to one another with the aid of connecting portions.

The actuator connectors can be arranged spaced apart from one another in triangular fashion, with an angle of 120° between them. The connecting portions form a triangular geometry that connects the actuator connectors to one another. The connecting portions may be part of the base portion. The connecting portions stiffen the actuator connectors by virtue of the connecting portions connecting the actuator connectors to one another. The connecting portions may meet at a central joining region of the base portion. The joining region is used to connect measurement targets to the optical element.

According to an embodiment, the connecting portions are mechanically decoupled from the base portion with the aid of cutouts.

The cutouts may be provided as gaps. The cutouts may be introduced into the base portion, for example using a milling method or an eroding method. However, the cutouts do not completely separate the connecting portions from the base portion, and so the connecting portions are still connected to the base portion.

According to an embodiment, the optical element furthermore comprises a plurality of measurement targets that are configured to interact with a measurement beam of a measuring instrument, with the measurement targets being provided on the base portion.

The measurement targets can be attached to the aforementioned joining region. The measurement targets may also be referred to as measurement marks. Each measurement target can comprise a mirror or a mirror surface that is suitable for reflecting the measurement beam back to the measuring instrument. There may be any desired number of measurement targets. However, six measurement targets can be provided. The measurement targets can be securely connected to the base portion, for example by being screwed on. The measurement targets may also be adhesively bonded to the base portion. Since the measurement targets are provided on the stiff base portion, rigid body movements of the optical element can be measured without disturbing natural vibrations. The measurement beam can be a laser beam.

According to an embodiment, a joining region of the base portion extends laterally beyond the mirror portion.

In the present case, “laterally” should be understood to mean in a direction parallel to the back side of the mirror portion. In particular, this means that the mirror portion does not cover the joining region. The joining region is part of the base portion. An asymmetrical structure of the mirror body or of the optical element may be achieved as a result of the joining region extending laterally beyond the mirror portion. As a result, the joining region can be easily accessible and may carry the measurement targets. At least some of the measurement targets can be provided in the joining region. However, it can be desirable for all measurement targets to be attached to the joining region.

According to an embodiment at least one of the actuator connectors is provided in the joining region.

Optionally, exactly one of the actuator connectors is provided in the joining region. This actuator connector can extend out of the joining region on the back side.

According to an embodiment, the mirror body is actively cooled.

For example, active cooling may be realized or implemented by virtue of the optical element or the mirror body having cooling channels through which a coolant, for example water, is guided in order to cool or heat the optical element or the mirror body. In this case, “active” means that, in particular, the coolant is pumped through the cooling channels with the aid of a pump or the like in order to extract heat from or supply heat to the optical element or the mirror body. However, heat can be extracted from the optical element or the mirror body in order to cool the optical element or the mirror body.

According to an embodiment, cooling channels are guided through the mirror body for the purposes of actively cooling the mirror body.

For example, the cooling channels are provided in the base portion of the mirror body. However, the cooling channels may also be provided in the mirror portion and/or in the rib structure. Any desired number of cooling channels may be provided. The cooling channels can be connected to one another. The cooling channels can form a cooling circuit or are part of a cooling circuit. The cooling circuit may comprise the aforementioned pump. The coolant circulates in the cooling circuit. Connections for the cooling circuit or for the cooling channels may be provided in the aforementioned joining region. This can help make the connections particularly accessible.

Further, an optical system, such as a projection optical unit, for a projection exposure apparatus having at least one such optical element and a plurality of actuators is proposed, which actuators are connected to the actuator connectors for the purpose of adjusting the at least one optical element.

The optical system may can comprise a multiplicity of such optical elements. For example, the optical system may comprise six, seven or eight such optical elements. The actuators might be what are known as Lorentz actuators. In the present case and as mentioned above, “adjusting” or “aligning” the optical element should be understood to mean moving the optical element from its actual pose to its target pose. Three actuators can be assigned to the optical element, with one of the actuators being coupled to each actuator connector. All six degrees of freedom of the optical element may be adjusted with the aid of the three actuators. The actuators may be part of an adjustment device of the optical system. The adjustment device may comprise an open-loop and closed-loop control unit for controlling the actuators. The optical system may comprise the measuring instrument that interacts with the measurement targets in order to capture the position of the optical element. For example, the measuring instrument may be an interferometer. For example, the actual pose of the optical element may be captured with the aid of the measuring instrument and the measurement targets. Then, the optical element may be moved from the actual pose to its target pose with the aid of the actuators. The open-loop and closed-loop control unit then can control the actuators on the basis of measurement signals from the measuring instrument.

Further, a projection exposure apparatus having at least one such optical element and/or one such optical system is proposed.

The projection exposure apparatus may comprise any desired number of optical elements. For example, the optical system can be a projection optical unit of the projection exposure apparatus. However, the optical system may also be an illumination optical unit of the projection exposure apparatus. The projection exposure apparatus may be an EUV lithography apparatus. EUV stands for “extreme ultraviolet” and refers to a wavelength of the operating light of between 1.0 nm and 30 nm. The projection exposure apparatus may also be a DUV lithography apparatus. DUV stands for “deep ultraviolet” and refers to a wavelength of the operating light of between 30 nm and 250 nm.

“A” or “an” in the present case should not necessarily be understood as being restricted to exactly one element. Rather, there may also be a plurality of elements, such as two, three or more. Any other numeral used here should also not be understood as restrictive to exactly the stated number of elements. Rather, numerical deviations upward and downward are possible, unless otherwise indicated.

The embodiments and features described for the optical element are correspondingly applicable to the proposed optical system and/or to the proposed projection exposure apparatus, and vice versa.

Further possible implementations of the disclosure also comprise non-explicitly mentioned combinations of features or embodiments described previously or hereinafter with regard to the exemplary embodiments. A person skilled in the art will also add individual aspects as improvements or additions to the respective basic form of the disclosure.

Further embodiments and aspects of the disclosure are the subject matter of the dependent claims and of the exemplary embodiments of the disclosure described below. The disclosure will be explained in detail hereinafter on the basis of certain embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic perspective view of an embodiment of an optical element for the projection exposure apparatus according to FIG. 1;

FIG. 3 shows a further schematic perspective view of the optical element according to FIG. 2;

FIG. 4 shows a schematic back view of the optical element according to FIG. 2;

FIG. 5 shows a schematic perspective view of a further embodiment of an optical element for the projection exposure apparatus according to FIG. 1;

FIG. 6 shows a further schematic perspective view of the optical element according to FIG. 5;

FIG. 7 shows a further schematic perspective view of the optical element according to FIG. 5;

FIG. 8 shows a schematic back view of the optical element according to FIG. 5; and

FIG. 9 shows a schematic view of an embodiment of an optical system for the projection exposure apparatus according to FIG. 1.

### DETAILED DESCRIPTION

Unless indicated to the contrary, elements that are identical or functionally identical have been provided with the same reference signs in the figures. It should also be noted that the illustrations in the figures are not necessarily to scale.

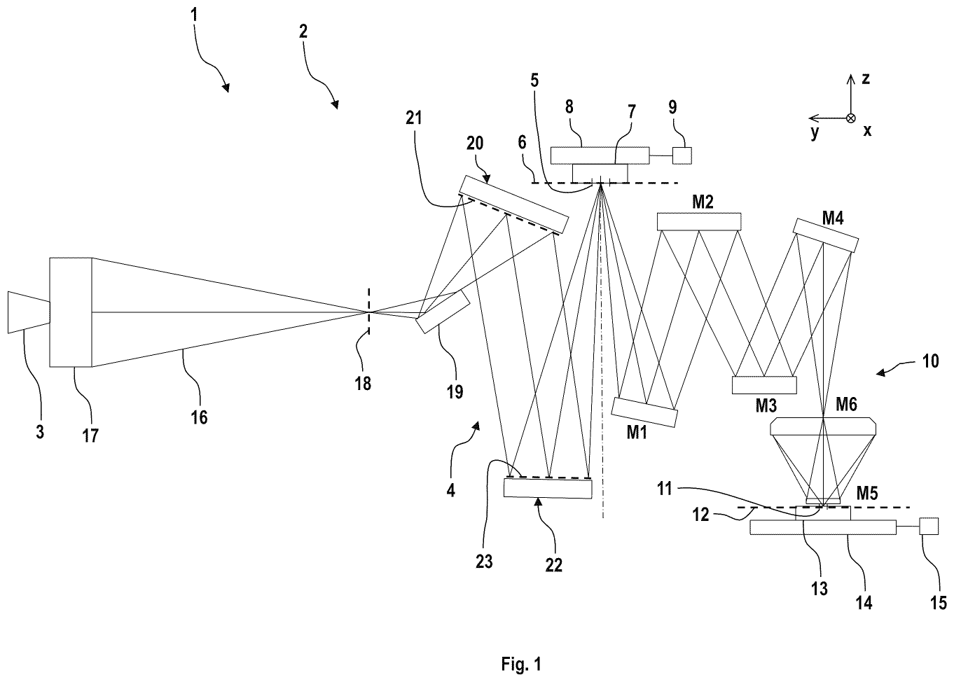

FIG. 1 shows one embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not include the light source 3.

A reticle 7 arranged in the object field 5 is exposed. The reticle 7 is held by a reticle holder 8. The reticle holder 8 is displaceable by way of a reticle displacement drive 9, in particular in a scanning direction.

FIG. 1 shows, by way of illustration, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. In an alternative, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular in the y-direction y. The displacement firstly of the reticle 7 by way of the reticle displacement drive 9 and secondly of the wafer 13 by way of the wafer displacement drive 15 may be implemented so as to be mutually synchronized.

The light source 3 is an EUV radiation source. The light source 3 emits in particular EUV radiation 16, which is also referred to below as used radiation, illumination radiation or illumination light. In particular, the used radiation 16 has a wavelength in the range between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, both to optimize its reflectivity for the used radiation and to suppress extraneous light.

Downstream of the collector 17, the illumination radiation 16 propagates through an intermediate focus in an intermediate focal plane 18. The intermediate focal plane 18 may represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, in an alternative to that, a mirror with a beam-influencing effect going beyond the pure deflection effect. In an alternative to that or in addition, the deflection mirror 19 may be in the form of a spectral filter that separates a used light wavelength of the illumination radiation 16 from extraneous light at a different wavelength. If the first facet mirror 20 is arranged in a plane of the illumination optical unit 4 which is optically conjugate to the object plane 6 as a field plane, then this facet mirror is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may take the form of macroscopic facets, in particular as rectangular facets or as facets with an arc-shaped or part-circular edge contour. The first facets 21 may take the form of plane facets or, in an alternative to that, convexly or concavely curved facets.

As is known for example from DE 10 2008 009 600 A1, the first facets 21 themselves may each also be composed of a multiplicity of individual mirrors, in particular a multiplicity of micromirrors. The first facet mirror 20 may take the form of a microelectromechanical system (MEMS system) in particular. For details, reference is made to DE 10 2008 009 600 A1.

The illumination radiation 16 propagates horizontally, i.e. in the y-direction y, between the collector 17 and the deflection mirror 19.

In the beam path of the illumination optical unit 4, a second facet mirror 22 is disposed downstream of the first facet mirror 20. Provided the second facet mirror 22 is arranged in a pupil plane of the illumination optical unit 4, it is also referred to as a pupil facet mirror. The second facet mirror 22 may also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or alternatively may be facets composed of micromirrors. In this regard, reference is also made to DE 10 2008 009 600 A1.

The second facets 23 may have plane reflection surfaces or, in an alternative to that, convexly or concavely curved reflection surfaces.

The illumination optical unit 4 thus forms a double-faceted system. This fundamental principle is also referred to as a fly's eye integrator.

It may be desirable to arrange the second facet mirror 22 not exactly in a plane that is optically conjugate to a pupil plane of the projection optical unit 10. In particular, the second facet mirror 22 may be arranged so as to be tilted in relation to a pupil plane of the projection optical unit 10, as described for example in DE 10 2017 220 586 A1.

With the aid of the second facet mirror 22, the individual first facets 21 are imaged into the object field 5. The second facet mirror 22 is the last beam-shaping mirror or actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror or, in an alternative to that, two or more mirrors, which are arranged one behind another in the beam path of the illumination optical unit 4. The transfer optical unit might in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 may also be omitted, and so downstream of the collector 17 the illumination optical unit 4 may then have exactly two mirrors, specifically the first facet mirror 20 and the second facet mirror 22.

The imaging of the first facets 21 into the object plane 6 via the second facets 23, or using the second facets 23, and a transfer optical unit is generally only an approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and may also be greater than 0.6 and may be, for example, 0.7 or 0.75.

Reflection surfaces of the mirrors Mi may be in the form of free-form surfaces without an axis of rotational symmetry. In an alternative to that, the reflection surfaces of the mirrors Mi may be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings may take the form of multilayer coatings, in particular with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y may be of approximately the same magnitude as a z-distance between the object plane 6 and the image plane 12.

In particular, the projection optical unit 10 may have an anamorphic design. It has in particular different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This may in particular result in illumination according to the Köhler principle. The far field is decomposed into a multiplicity of object fields 5 with the aid of the first facets 21. The first facets 21 create a plurality of images of the intermediate focus on the second facets 23 respectively assigned to them.

By way of an assigned second facet 23, the first facets 21 are each imaged onto the reticle 7 and overlaid over one another for the purpose of illuminating the object field 5. The illumination of the object field 5 is in particular as homogeneous as possible. It can have a uniformity error of less than 2%. Field uniformity may be achieved by superposing different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, in particular the subset of the second facets 23, which guide light. This intensity distribution is also referred to as illumination setting or illumination pupil filling.

A likewise preferred pupil uniformity in the region of sections of an illumination pupil of the illumination optical unit 4 that are illuminated in a defined manner may be achieved by a redistribution of the illumination channels.

Further aspects and details of the illumination of the object field 5 and in particular of the entrance pupil of the projection optical unit 10 are described below.

The projection optical unit 10 may have a homocentric entrance pupil in particular. The latter may be accessible. It may also be inaccessible.

The entrance pupil of the projection optical unit 10 regularly cannot be exactly illuminated with the second facet mirror 22. In the case of an imaging process of the projection optical unit 10 that images the center of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area conjugate thereto in real space. In particular, this area exhibits a finite curvature.

It may be the case that the projection optical unit 10 has different positions of the entrance pupil for the tangential beam path and for the sagittal beam path. In this case, an imaging element, in particular an optical structural element of the transfer optical unit, should be provided between the second facet mirror 22 and the reticle 7. Using this optical element, the different positions of the tangential entrance pupil and the sagittal entrance pupil may be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is in a tilted arrangement in relation to the object plane 6. The first facet mirror 20 is in a tilted arrangement in relation to an arrangement plane defined by the deflection mirror 19. The first facet mirror 20 is in a tilted arrangement in relation to an arrangement plane defined by the second facet mirror 22.

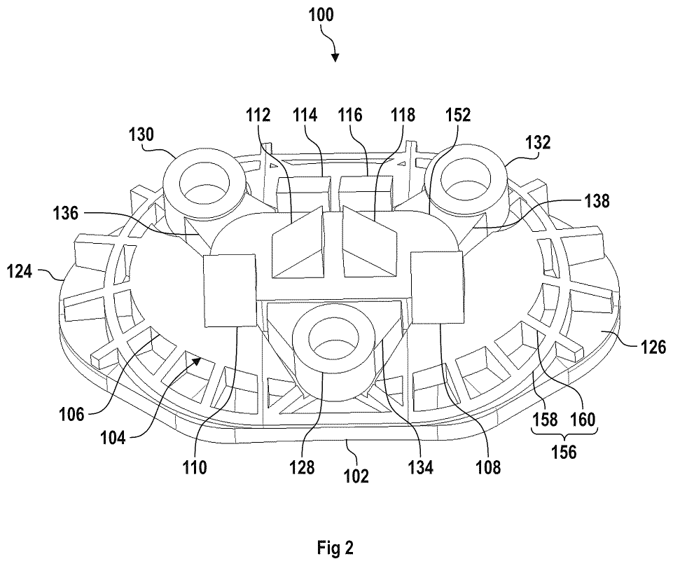

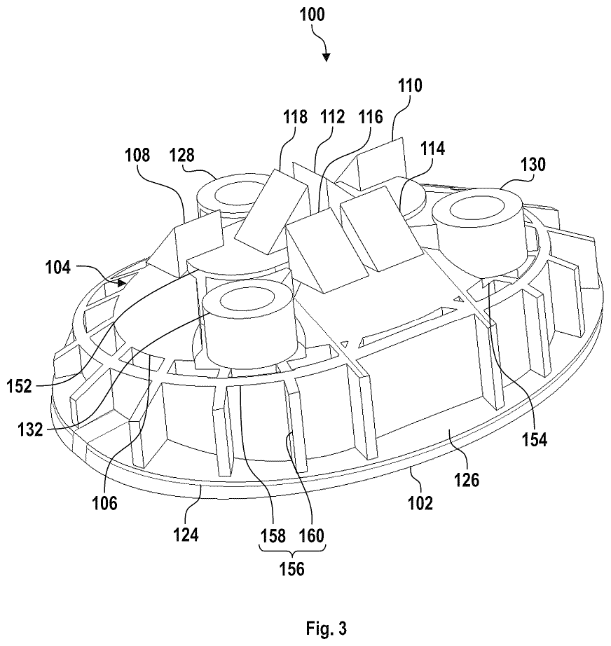

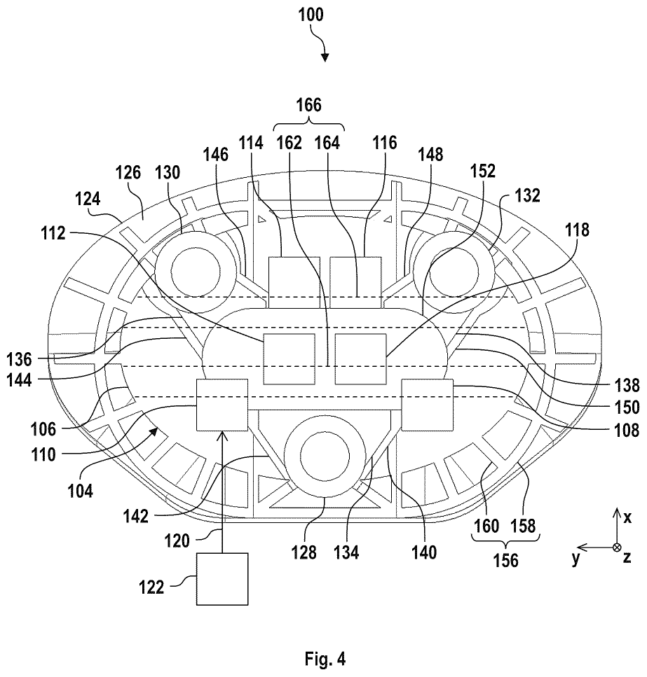

FIG. 2 shows a schematic perspective view of an embodiment of an optical element 100. FIG. 3 shows a further schematic perspective view of the optical element 100. FIG. 4 shows a schematic bottom view of the optical element 100. In the following reference is made to FIGS. 2 to 4 simultaneously.

The development of projection exposure apparatuses 1 with a high numerical aperture (NA) has a direct impact on the design of mirrors M1 to M6 in projection optical unit 10. The higher the NA value, the larger and heavier mirrors M1 to M6 become. The manufacturing costs scale disproportionately with the size of the respective mirror M1 to M6. However, in order to minimize the production costs of larger mirrors M1 to M6, the aim is to switch to a lightweight mirror design by saving material on the mirrors M1 to M6.

Accordingly, the optical element 100 is one of the mirrors M1 to M6. The optical element 100 comprises an optically effective or optically active surface 102 that is oriented downward in the orientation of FIGS. 2 to 4. The optically active surface 102 is suitable for reflecting illumination radiation 16, in particular EUV radiation. The optically active surface 102 is a mirror surface. The optically active surface 102 may be curved, in particular toroidally curved.

The optically active surface 102 is provided on the front side of a mirror body 104 of the optical element 100. The optically active surface 102 may be produced by way of coating. The mirror body 104 may also be referred to as mirror substrate. For example, the mirror body 104 element is made from ceramics or glass-ceramics.

The mirror body 104 comprises a block-shaped base portion 106. The base portion 106 may have a cylindrical geometry with an oval or circular base. The base portion 106 may have any desired geometry. The base portion 106 is in the form of a solid body and has high stiffness as a result. The base portion 106 may be provided approximately centrally on the mirror body 104.

On account of the high stiffness of the base portion 106 in comparison with the remaining mirror body 104, sensors or, as shown in FIGS. 2 to 4, what are known as measurement targets 108, 110, 112, 114, 116, 118 may be attached to the base portion 106. Six measurement targets 108, 110, 112, 114, 116, 118 may be provided. The measurement targets 108, 110, 112, 114, 116, 118 may also be referred to as measurement marks. The measurement targets 108, 110, 112, 114, 116, 118 may comprise mirrors or be mirrors.

For example, as shown in FIG. 4 on the basis of the measurement target 110, a measurement beam 120 from a measuring instrument 122 may be steered to the respective measurement target 108, 110, 112, 114, 116, 118. A pose of the optical element 100 may be captured with the aid of the measurement targets 108, 110, 112, 114, 116, 118 and the measuring instrument 122.

The optical element 100 can have six degrees of freedom. All six degrees of freedom may be captured with the aid of the measurement targets 108, 110, 112, 114, 116, 118. In particular, the optical element 100 has three translational degrees of freedom in the x-direction x, the y-direction y and the z-direction z. In addition, the optical element 100 has three rotational degrees of freedom, respectively about the x-direction x, the y-direction y and the z-direction z.

In the present case, a “position” of the optical element 100 should be understood to mean its coordinates or the coordinates of a measurement point provided on the optical element 100 with respect to the x-direction x, the y-direction y and the z-direction z. In the present case, the “orientation” of the optical element 100 should be understood to mean its tilt or the tilt of the measurement point about the x-direction x, the y-direction y and the z-direction z. In the present case, the “pose” of the optical element 100 should accordingly be understood to mean both the position and the orientation of the optical element 100.

In addition to the base portion 106 the optical element 100 comprises a slab-shaped or panel-shaped mirror portion 124. Considered in the z-direction z, the mirror portion 124 has substantially lower material strength than the base portion 106. In the plan view, the mirror portion 124 may be oval or triangular, for example. The mirror portion 124 may extend around the base portion 106 in full.

The optically active surface 102 is provided on the front side of the mirror portion 124. The mirror portion 124 has a back side 126 facing away from the optically active surface 102. The back side 126 has no reflective properties. As a result of the mirror portion 124 having a thinner wall in comparison with the base portion 106, the mirror portion 124 is softer or less stiff.

The mirror portion 124 and the base portion 106 are formed in one piece, in particular from one piece of material. In this case, “in one part” or “in one piece” means that the mirror portion 124 and the base portion 106 are not constructed from different components but form a common component. In the present case, “from one piece of material” means that the mirror portion 124 and the base portion 106 are manufactured from the same material throughout. Consequently, the mirror body 104 is monolithic or may be referred to as monolithic. For example, the mirror body 104 is produced by suitable grinding of a substrate block.

In an alternative to that, the base portion 106 and the mirror portion 124 may also be two separate components or component parts of the optical element 100, which are securely connected to each other. This can result in the possibility of manufacturing the base portion 106 and the mirror portion 124 from different materials. For example, it is possible to use materials with different coefficients of thermal expansion (CTEs).

For example, one component of the optical element 100 may consist of a 0-CTE material and at least one further component may be manufactured from an easily processible and cost-effective material, which is suitable for a light structure. Ceramic materials are particularly well suited in this case. In this case, it is possible to provide active cooling in order to compensate the CTE difference between the various materials. The components to be connected may either be bonded or adhesively bonded.

Furthermore, the optical element 100 may be composed of many simple individual parts. Various joining methods are possible to this end. For example, it is possible to use adhesion, screen printing, laser bonding, surface activated bonding, anodic bonding, glass frit bonding, adhesive bonding, eutectic bonding, reactive bonding, silicate bonding or the like.

Actuator interfaces or actuator connectors 128, 130, 132 may be provided on the base portion 106. For example, three actuator connectors 128, 130, 132 are provided and arranged in the form of a triangle, offset from one another by 120°. In particular, a first actuator connector 128, a second actuator connector 130 and a third actuator connector 132 are provided.

The actuator connectors 128, 130, 132 are cylindrical. Actuating elements or actuators may be connected to the actuator connectors 128, 130, 132. The actuators connected to the actuator connectors 128, 130, 132 may be what are known as Lorentz actuators for example. However, other actuators, for example piezoelectric elements or the like, may also be used. The pose of the optical element 100 may be adjusted with the aid of the actuators.

The actuator connectors 128, 130, 132 are provided on the base portion 106. The actuator connectors 128, 130, 132 are rigidly connected to one another with the aid of triangularly arranged connecting portions 134, 136, 138. The connecting portions 134, 136, 138 may be part of the base portion 106 or at least be securely connected thereto. Cutouts 140, 142, 144, 146, 148, 150 (FIG. 4) may be provided between the connecting portions 134, 136, 138 and the base portion 106. The connecting portions 134, 136, 138 meet at a solid joining region 152, which is part of the base portion 106. The measurement targets 108, 110, 112, 114, 116, 118 are connected to the joining region 152.

Each actuator connector 128, 130, 132 is assigned a cutout or a decoupling point 154 (FIG. 3). With the aid of the decoupling points 154, the actuator connectors 128, 130, 132 and hence the actuators may be decoupled from the base portion 106. The decoupling points 154 are designed as slots which are provided between the base portion 106 and the respective actuator connector 128, 130, 132.

A significant reduction in mass can be achieved by designing the mirror portion 124 to have a thinner wall in comparison with the base portion 106. Vibrations as a consequence of exciting the natural modes of the mirror portion 124 will not impair the stability of the measurement targets 108, 110, 112, 114, 116, 118 provided on the base portion 106. Moreover, the actuators are connected to the base portion 106 with the aid of the actuator connectors 128, 130, 132 and the decoupling points 154, in order to allow decoupling of parasitic forces and torques.

Furthermore, a rib structure 156 may additionally also be provided and placed on the back side 126 of the mirror portion 124. As mentioned previously, the rib structure 156, the base portion 106 and the mirror portion 124 may form a component that is in one piece, in particular formed from one piece of material. Furthermore, the rib structure 156, the base portion 106 and the mirror portion 124 may be a plurality of separate components that are connected to one another in order to form the optical element 100.

The rib structure 156 may be honeycomb-shaped, honeycomb-like, truss-shaped or truss-like. For example, the rib structure 156 may comprise a circumferential rib 158 that extends around the base portion 106 and encloses the latter. In the plan view, the circumferential rib 158 may be oval or elliptical. Furthermore, the rib structure 156 comprises a multiplicity of connecting ribs 160, only one of which has been provided with a reference sign in each of FIGS. 2 to 4. Therefore, only one connecting rib 160 is discussed below. Starting from the base portion 106, the connecting rib 160 extends outward and connects the all-round circumferential rib 158 to the base portion 106. The connecting rib 160 may protrude beyond the circumferential rib 158 and extend to an edge of the mirror portion 124.

The rib structure 156 is supported by the base portion 106. The rib structure 156 may extend as desired in the x-direction x, the y-direction y and/or the z-direction z and may also branch out as desired. As mentioned above, the rib structure 156 may be honeycomb-shaped. The rib structure 156 ensures a certain amount of stiffening of the mirror portion 124, and hence of the entire mirror body 104. The rib structure 156 can be part of the mirror body 104.

The rib structure 156 moreover offers the option of attaching tuned mass dampers (TMDs) in order to damp certain natural modes. Where desired, it is likewise possible to stiffen individual actuator connectors 128, 130, 132 with the aid of the rib structure 156. The rib structure 156 can be formed in one piece with the base portion 106 and the mirror portion 124. Using the optical element 100 explained above, it is possible to obtain higher control bandwidths with lower masses of the mirror body 104 in comparison with known mirrors for projection optical units 10.

The optical element 100 may be actively cooled. For example, this active cooling may be realized or implemented by virtue of the optical element 100 or the mirror body 104 comprising cooling channels 162, 164, only two cooling channels 162, 164 of which are shown in a very schematic manner in FIG. 4. Any desired number of cooling channels 162, 164 may be provided. The cooling channels 162, 164 may extend through the base portion 106. However, the cooling channels 162, 164 may also or in addition to that extend within the rib structure 156 and/or within the mirror portion 124.

For dissipating heat from the optical element 100 or for controlling the temperature of the optical element 100, a coolant, for example water, is passed through the cooling channels 162, 164 in order to cool or heat the optical element 100. In particular, “controlling the temperature” means that the optical element 100 is kept at a certain temperature. Heat may be supplied or dissipated to this end.

In this case, “active” means that the coolant is pumped through the cooling channels 162, 164 with the aid of a pump or the like in order to extract heat from or supply heat to the optical element 100. However, heat can be extracted from the optical element 100 in order to cool the optical element. The cooling channels 162, 164 form a cooling circuit 166 or are part of a cooling circuit 166. The cooling circuit 166 may comprise the aforementioned pump. The coolant circulates in the cooling circuit 166.

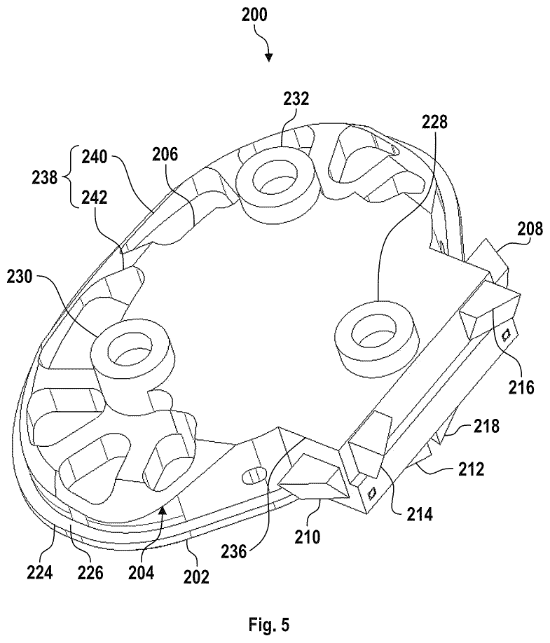

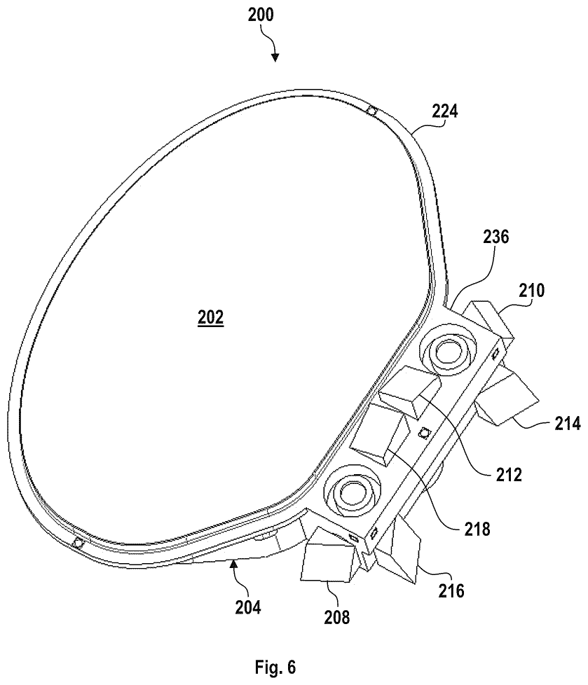

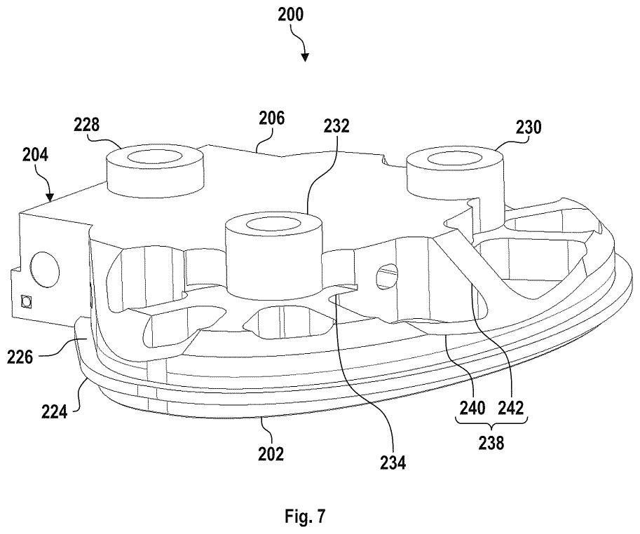

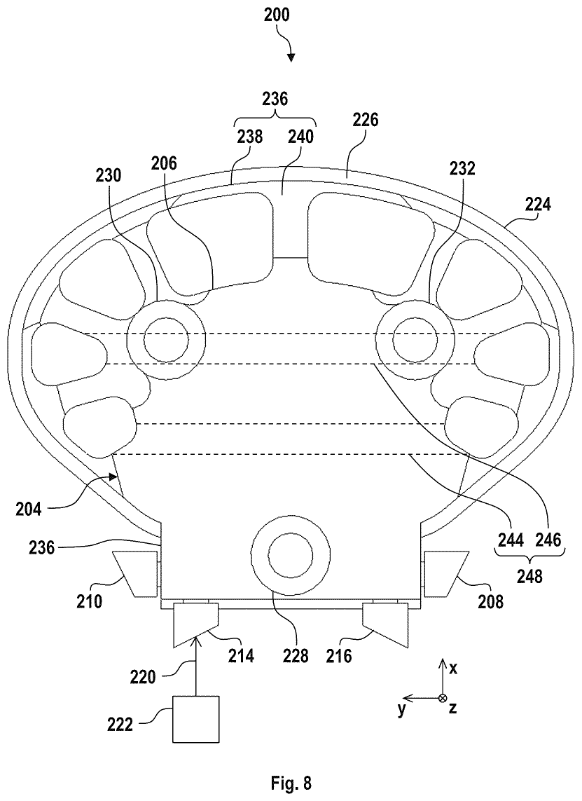

FIG. 5 shows a schematic perspective view of a further embodiment of an optical element 200. FIG. 6 shows a further schematic perspective view of the optical element 200. FIG. 7 shows a further schematic perspective view of the optical element 200. FIG. 8 shows a schematic bottom view of the optical element 100. In the following reference is made to FIGS. 5 to 8 simultaneously.

The optical element 200 may be one of the mirrors M1 to M6. The optical element 200 comprises an optically active surface 202 that is oriented upward in the orientation of FIG. 6. The optically active surface 202 is suitable for reflecting illumination radiation 16, in particular EUV radiation. The optically active surface 202 is a mirror surface. The optically active surface 202 may be curved, in particular toroidally curved.

The optically active surface 202 is provided on the front side of a mirror body 204 of the optical element 200. The optically active surface 202 may be produced by way of coating. The mirror body 204 may also be referred to as mirror substrate. For example, the mirror body 204 element is made from ceramics or glass-ceramics.

The mirror body 204 comprises a block-shaped base portion 206. The base portion 206 is constructed in unsymmetrical fashion. The base portion 206 may have any desired geometry. The base portion 206 is in the form of a solid body and has high stiffness as a result. The base portion 206 may be provided laterally on the mirror body 204.

On account of the high stiffness of the base portion 206 in comparison with the remaining mirror body 204, sensors or, as shown in FIGS. 4 to 6 and 8, what are known as measurement targets 208, 210, 212, 214, 216, 218 may be attached to the base portion 206. Six measurement targets 208, 210, 212, 214, 216, 218 may be provided. The measurement targets 208, 210, 212, 214, 216, 218 may also be referred to as measurement marks. The measurement targets 208, 210, 212, 214, 216, 218 may comprise mirrors or be mirrors.

For example, as shown in FIG. 8 on the basis of the measurement target 214, a measurement beam 220 from a measuring instrument 222 may be steered to the respective measurement target 208, 210, 212, 214, 216, 218. A pose of the optical element 200 may be captured with the aid of the measurement targets 208, 210, 212, 214, 216, 218 and the measuring instrument 222.

In addition to the base portion 206 the optical element 200 comprises a slab-shaped or panel-shaped mirror portion 224. Considered in the z-direction z, the mirror portion 224 has substantially lower material strength than the base portion 206. In the plan view, the mirror portion 224 may be oval or triangular, for example. The mirror portion 224 may extend around the base portion 206 in full. However, this is not mandatory.

The optically active surface 202 is provided on the front side of the mirror portion 224. The mirror portion 224 has a back side 226 facing away from the optically active surface 202. The back side 226 has no reflective properties. As a result of the mirror portion 224 having a thinner wall in comparison with the base portion 106, the mirror portion 224 is softer or less stiff.

The mirror portion 224 and the base portion 206 are formed in one piece, in particular from one piece of material. Consequently, the mirror body 204 is monolithic or may be referred to as monolithic. For example, the mirror body 204 is produced by suitable grinding of a substrate block. In an alternative to that and as explained above in relation to the optical element 100, the base portion 206 and the mirror portion 224 may also be two separate components or component parts of the optical element 100, which are securely connected to each other.

Actuator interfaces or actuator connectors 228, 230, 232 may be provided on the base portion 206. For example, three actuator connectors 228, 230, 232 are provided and arranged in the form of a triangle, offset from one another by 120°. In particular, a first actuator connector 228, a second actuator connector 230 and a third actuator connector 232 are provided. The actuator connectors 228, 230, 232 are cylindrical. As already explained above with reference to the optical element 100, actuating elements or actuators may be connected to the actuator connectors 228, 230, 232. The pose of the optical element 200 may be adjusted with the aid of the actuators.

The actuator connectors 228, 230, 232 are provided on the base portion 206. Each actuator connector 228, 230, 232 may be assigned a cutout or a decoupling point 234 (FIG. 7). However, this is not mandatory. In the present case, only the actuator connectors 230, 232 are cut out and thus decoupled from the base portion 206. The first actuator connector 228 has no such decoupling point 234 in this case. However, all actuator connectors 228, 230, 232 may also have such a decoupling point 234.

The type of decoupling and the number of actuators to be decoupled may vary depending on the arrangement (reflected about a longitudinal axis) and the pose (central or off centered) of the actuators. Exactly one actuator or two actuators or all three actuators may be decoupled from the base portion 206. With the aid of the decoupling points 234, the actuator connectors 228, 230, 232 and hence the actuators may thus be decoupled from the base portion 206. The decoupling points 234 are designed as gaps or slots which are provided between the base portion 206 and the respective actuator connector 228, 230, 232.

A solid joining region 236, which is part of the base portion 206, extends laterally from the base portion 206. The joining region 236 extends laterally beyond the mirror portion 224. The measurement targets 208, 210, 212, 214, 216, 218 are connected to the joining region 236.

A significant reduction in mass can be achieved by designing the mirror portion 224 to have a thinner wall in comparison with the base portion 206. Vibrations as a consequence of exciting the natural modes of the mirror portion 224 will not impair the stability of the measurement targets 208, 210, 212, 214, 216, 218 provided on the base portion 206, in particular on the joining region 236. Moreover, the actuators are connected to the base portion 206 with the aid of the actuator connectors 228, 230, 232 and the decoupling points 234, in order to allow decoupling of parasitic forces and torques.

Furthermore, a rib structure 238 may additionally also be provided and placed on the back side 226 of the mirror portion 224. As mentioned previously, the rib structure 238, the base portion 206 and the mirror portion 224 may form a component that is in one piece, in particular formed from one piece of material. Furthermore, the rib structure 238, the base portion 206 and the mirror portion 224 may be a plurality of separate components that are connected to one another in order to form the optical element 200.

The rib structure 238 may be truss-shaped or truss-like. For example, the rib structure 238 may comprise a circumferential rib 240, which extends around the base portion 206 at least in sections; the circumferential rib 240 may be oval or elliptical in the plan view. Furthermore, the rib structure 238 comprises a multiplicity of connecting ribs 242, only one of which has been provided with a reference sign in FIGS. 5, 7 and 8. Therefore, only one connecting rib 242 is discussed below. Starting from the base portion 206, the connecting rib 242 extends outward and connects the all-round circumferential rib 240 to the base portion 206. The connecting rib 242 can end at the all-round circumferential rib 240.

The rib structure 238 is supported by the base portion 206. The rib structure 238 may extend as desired in the x-direction x, the y-direction y and/or the z-direction z and may also branch out as desired. The rib structure 238 ensures a certain amount of stiffening of the mirror portion 224, and hence of the entire mirror body 204. The rib structure 238 is part of the mirror body 204.

The optical element 200, like the optical element 100, may be actively cooled via a coolant. For example, this active cooling may be realized or implemented by virtue of the optical element 200 or the mirror body 204 comprising cooling channels 244, 246, only two cooling channels 244, 246 of which are shown in a very schematic manner in FIG. 8. Any desired number of cooling channels 244, 246 may be provided.

The cooling channels 244, 246 may extend through the base portion 206. However, the cooling channels 244, 246 may also or in addition to that extend within the rib structure 238 and/or within the mirror portion 224. The cooling channels 244, 246 form a cooling circuit 248 or are part of a cooling circuit 248. The cooling circuit 248 may comprise a pump. The coolant circulates in the cooling circuit 248. Connections for the cooling circuit 248 or for the cooling channels 244, 246 may be provided in the joining region 236. This makes the connections particularly accessible.

With the aid of the two embodiments of the optical element 100, 200, a lightweight mirror design can be realized, which despite material saving has good dynamics with regard to the control bandwidth and a good optical performance with regard to wavefront aberrations. The optically active surface 102, 202 is supported by the rib structure 156, 238 in the process.

More material is attached to the base portion 106, 206 on the back side of the optical element 100, 200 in order to rigidly attach the measurement targets 108, 110, 112, 114, 116, 118, 208, 210, 212, 214, 216, 218 to the mirror body 104, 204. The latter is important in the closed-loop control of the optical element 100, 200. The three actuator connectors 128, 130, 132, 228, 230, 232 are arranged 120° offset from one another and rigidly connected to the base portion 106, 206.

The lightweight mirror design may be refined, calculated and optimized in a plurality of iterative design loops and calculation loops. In the process, the actuator connectors 128, 130, 132, 228, 230, 232 are firstly varied relative to a center of the optical element 100, 200. Secondly, different stiffening options are investigated and the orientation of the measurement targets 108, 110, 112, 114, 116, 118, 208, 210, 212, 214, 216, 218 is modified iteratively in order to find an optimal compromise between controllability and natural frequency. Moreover, the arrangement and geometry of the rib structure 156, 238 is adapted, and a decoupling of the actuator connectors 128, 130, 132, 228, 230, 232 is incorporated in the optically active surface 102, 202.

The lightweight mirror design of the optical element 100, 200 has a higher first natural frequency and a high control bandwidth in comparison with a solid reference mirror. An evaluation of the mass of the optical element 100, 200 in comparison to the reference mirror yields a weight reduction of about 61%. The raw material need is reduced by about 44% in the process. With the material savings achieved by this lightweight mirror design, the production costs for producing the optical element 100, 200 are significantly reduced.

A reduction in production costs is achieved by leaving out material in the optical element 100, 200. Material is omitted wherever it is possible and effective. As a result of the conversion to the lightweight mirror design, the optical element 100, 200, which was previously modeled as a solid block, now consists of a thin-walled panel in the form of the mirror portion 124, 224, which is supported by the stiff rib structure 156, 238 on the back side 126, 226, and the base portion 106, 206. The optically active surface 102, 202 is provided on the front side of the thin-walled mirror portion 124, 224.

Since the lightweight mirror design is thin-walled, an optimized concept was worked out as regards the connection of the measurement targets 108, 110, 112, 114, 116, 118, 208, 210, 212, 214, 216, 218 and actuator connectors 128, 130, 132, 228, 230, 232. The measurement targets 108, 110, 112, 114, 116, 118, 208, 210, 212, 214, 216, 218 for measuring the optical element 100, 200 are combined in a common region or point, in particular an adjustment point in the form of the joining regions 152, 236. That is to say, the six measurement targets 108, 110, 112, 114, 116, 118, 208, 210, 212, 214, 216, 218 are attached to the back side of the optical element 100, 200 and rigidly attached to the adjustment point.

The stiff connection of the measurement targets 108, 110, 112, 114, 116, 118, 208, 210, 212, 214, 216, 218 is realized by filling cavities in the base portion 106, 206 with material and connecting the measurement targets 108, 110, 112, 114, 116, 118, 208, 210, 212, 214, 216, 218 to the base portion 106, 206. The orientation of the individual measurement targets 108, 110, 112, 114, 116, 118, 208, 210, 212, 214, 216, 218 is optimized with respect to a direction of the respective measurement beam 122, 222 and selected in such a way that the control bandwidth of the optical element 100, 200 is increased.

In order to ensure that the optical element 100, 200 can continue to be mounted rigidly despite the great reduction in mass, the actuator connectors 128, 130, 132, 228, 230, 232 are positioned centrally and offset by 120° from one another on the back side of the mirror body 104, 204. Moreover, the connection of the actuator connectors 128, 130, 132, 228, 230, 232 to base portion 106, 206 is reinforced.

The actuator connectors 128, 130, 132, 228, 230, 232 can have identical structures. A respective geometry of the actuator connectors 128, 130, 132, 228, 230, 232 is selected in such a way that induced deformations of the optically active surface 102, 202 due to various effects, such as assembly, pressure variation, acceleration, gravity or the like, are reduced.

A further decoupling measure for decoupling the optically active surface 102, 202 from the introduction of loads on the actuator connectors 128, 130, 132, 228, 230, 232 is realized with the aid of the decoupling points 154, 234. In a plane spanned by the x-direction x and the y-direction y, the actuator connectors 128, 130, 132, 228, 230, 232 are separated from the base portion 106, 206 in the transverse direction with the aid of the decoupling points 154, 234, whereby a direct flow of force into the optically active surface 102, 202 is interrupted.

The difference between the optical element 100, 200 and the previous mirror design according to the reference mirror is substantially found in the reduction of the mirror material. This may significantly reduce the production costs. A further difference in the lightweight mirror design from the point of view of dynamics lies in a higher natural frequency, despite the reduction in weight, on account of the stiff connection of the measurement targets 108, 110, 112, 114, 116, 118, 208, 210, 212, 214, 216, 218 and actuator connectors 128, 130, 132, 228, 230, 232 and in the reduced material displacement at the edge of the mirror portion 124, 224.

The higher natural frequency in turn results in a high control bandwidth of the optical element 100, 200, which plays an important role for the controllability of the optical element 100, 200. Moreover, on account its significant reduction in mass, the lightweight mirror design offers more leeway for the design of the actuators.

Finally, the actuator connectors 128, 130, 132, 228, 230, 232 of the optical element 100, 200 have different dimensions in comparison with the reference mirror and are also decoupled from the optically active surface 102, 202, in order to keep lower the deformations induced in the optically active surface 102, 202 by way of the considerable reduction in mass and the associated loss of stiffness.

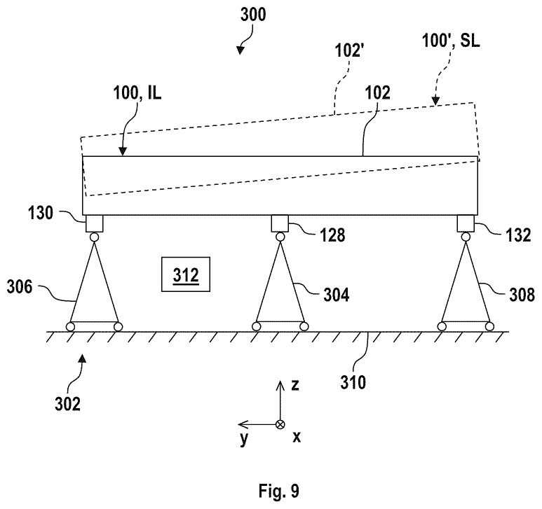

FIG. 9 shows a schematic view of an embodiment of an optical system 300 for the projection exposure apparatus 1.

The optical system 300 may be a projection optical unit 10 as explained above or part of such a projection optical unit 10. Therefore, the optical system 300 may also be referred to as projection optical unit 10. However, the optical system 300 may also be an illumination optical unit 4, as explained previously, or part of such an illumination optical unit 4. Therefore, the optical system 300 may alternatively also be referred to as illumination optical unit 4. However, the following text assumes that the optical system 300 is a projection optical unit 10 or part of such a projection optical unit 10.

The optical system 300 may comprise a plurality of optical elements 100, 200, only one optical element 100 of which is shown in FIG. 9 however. Therefore, only the optical element 100 is referred to below. All of the following statements relating to the optical element 100 are applicable accordingly to the optical element 200. This means that, in particular, the optical system 300 may comprise both the optical element 100 and the optical element 200.

In the orientation of FIG. 9, the optically active surface 102 faces upward. The actuator connectors 128, 130, 132 are provided on the back side of the optical element. The optical element 100 or the optically active surface 102 has six degrees of freedom, as mentioned previously, to be precise three translational degrees of freedom, respectively in the x-direction x, the y-direction y and the z-direction z, and three rotational degrees of freedom respectively about the x-direction x, the y-direction y and the z-direction z.

FIG. 9 shows an actual pose IL of the optical element 100 or of the optically active surface 102 in solid lines and a target pose SL of the optical element 100 or of the optically active surface 102 in dashed lines and using the reference signs 100′ and 102′. The optical element 100 may be brought from its actual pose IL to the target pose SL and vice versa. For example, the optical element 100 in the target pose SL meets specific optical specifications or desired properties that the optical element 100 in the actual pose IL does not meet.

In order to move the optical element 100 from the actual pose IL to the target pose SL, the optical system 300 comprises an adjustment device 302. The adjustment device 302 is configured to adjust the optical element 100. In the present case, an “adjustment” or “alignment” of the optical element 100 should be understood to mean, in particular, a change in the pose of the optical element 100. For example, the optical element 100 may be moved from the actual pose IL to the target pose SL and vice versa with the aid of the adjustment device 302. The adjustment or alignment of the optical element 100 may thus be implemented with the aid of the adjustment device 302 in all six aforementioned degrees of freedom.

The adjustment device 302 comprises a plurality of actuating devices or actuators 304, 306, 308, which are shown in only very schematic fashion in FIG. 9. Each actuator connector 128, 130, 132 is assigned an actuator 304, 306, 308. In particular, this means that exactly three actuators 304, 306, 308 are provided. An adjustment of the optical element 100 in all six degrees of freedom is possible by using the three actuators 304, 306, 308.

A first actuator 304 is assigned to the first actuator connector 128. A second actuator 306 is assigned to the second actuator connector 130. A third actuator 308 is assigned to the third actuator connector 132. The actuators 304, 306, 308 have identical constructions.

The actuators 304, 306, 308 may be coupled to a fixed world 310. The fixed world 310 may be a force frame or any other immovable structure. All actuators 304, 306, 308 are operatively connected to the open-loop and closed-loop control unit 312, and as a result the open-loop and closed-loop control unit 312 can adjust the optical element 100 in all six degrees of freedom with the aid of a suitable control of these actuators 304, 306, 308.

Although the present disclosure has been described with reference to exemplary embodiments, it is modifiable in various ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical element
100′ Optical element
102 Optically active surface
104 Mirror body
106 Base portion
108 Measurement target
110 Measurement target
112 Measurement target
114 Measurement target
116 Measurement target
118 Measurement target
120 Measurement beam
122 Measuring instrument
124 Mirror portion
126 Back side
128 Actuator connector
130 Actuator connector
132 Actuator connector
134 Connection portion
136 Connection portion
138 Connection portion
140 Cutout
142 Cutout
144 Cutout
146 Cutout
148 Cutout
150 Cutout
152 Joining region
154 Decoupling point
156 Rib structure
158 Circumferential rib
160 Connecting rib
162 Cooling channel
164 Cooling channel
166 Cooling circuit
200 Optical element
202 Optically active surface
204 Mirror body
206 Base portion
208 Measurement target
210 Measurement target
212 Measurement target
214 Measurement target
216 Measurement target
218 Measurement target
220 Measurement beam
222 Measuring instrument
224 Mirror portion
226 Back side
228 Actuator connector
230 Actuator connector
232 Actuator connector
234 Decoupling point
236 Joining region
238 Rib structure
240 Circumferential rib
242 Connecting rib
244 Cooling channel
246 Cooling channel
248 Cooling circuit
300 Optical system
302 Adjustment device
304 Actuator
306 Actuator
308 Actuator
310 Fixed world
312 Open-loop and closed-loop control unit
IL Actual pose
M1 Mirror
M2 Mirror
M3 Mirror
M4 Mirror
M5 Mirror
M6 Mirror
SL Target pose
X x-direction
y y-direction
Z z-direction

What is claimed is:

1. An optical element, comprising:
a mirror body comprising a mirror portion and a base portion extending from a back side of the mirror portion, the mirror portion comprising an optically active surface, the base portion being having a greater rigidity than the mirror portion;
a plurality of actuator connectors configured to connect actuators to the optical element, the actuator connectors being supported by the base portion; and
a rib structure attached to the back side of the mirror portion,
wherein the actuator connectors are mechanically decoupled from the base portion via decoupling points.

2. The optical element of claim 1, wherein the rib structure has a truss-like geometry or honeycomb-like geometry.

3. The optical element of claim 1, wherein the rib structure supports the mirror portion on the base portion.

4. The optical element of claim 1, wherein:
the rib structure comprises a circumferential rib and a plurality of connecting ribs;
at least sections of the rib extends around the base portion; and
the connecting ribs connect the base portion to the circumferential rib.

5. The optical element of claim 1, wherein the decoupling points comprise cutouts between the actuator connectors and the base portion.

6. The optical element of claim 1, wherein the actuator connectors are connected to one another via connecting portions.

7. The optical element of claim 6, wherein the connecting portions are mechanically decoupled from the base portion via cutouts.

8. The optical element of claim 1, further comprising a plurality of measurement targets configured to interact with a measurement beam, wherein the measurement targets are on the base portion.

9. The optical element of claim 1, wherein the base portion comprises a joining region extending laterally beyond the mirror portion.

10. The optical element of claim 9, wherein at least one of the actuator connectors is in the joining region.

11. The optical element of claim 1, wherein the mirror body is configured to be actively cooled.

12. The optical element of claim 1, wherein cooling channels passing therethrough pass through the mirror body.

13. The optical element of claim 1, wherein:
the rib structure has a truss-like geometry or honeycomb-like geometry; and
the rib structure supports the mirror portion on the base portion.

14. The optical element of claim 1, wherein:
the rib structure has a truss-like geometry or honeycomb-like geometry;
the rib structure comprises a circumferential rib and a plurality of connecting ribs;
at least sections of the rib extends around the base portion; and
the connecting ribs connect the base portion to the circumferential rib.

15. The optical element of claim 1, wherein:
the rib structure has a truss-like geometry or honeycomb-like geometry; and
the decoupling points comprise cutouts between the actuator connectors and the base portion.

16. The optical element of claim 1, wherein:
the rib structure has a truss-like geometry or honeycomb-like geometry; and
the actuator connectors are connected to one another via connecting portions.

17. The optical element of claim 1, further comprising a plurality of measurement targets configured to interact with a measurement beam, wherein the measurement targets are on the base portion, and the rib structure has a truss-like geometry or honeycomb-like geometry.

18. An optical system, comprising:
a plurality of actuators; and
an optical element, comprising:
a mirror body comprising a mirror portion and a base portion extending from a back side of the mirror portion, the mirror portion comprising an optically active surface, the base portion being having a greater rigidity than the mirror portion;
a plurality of actuator connectors configured to connect the actuators to the optical element, the actuator connectors being supported by the base portion; and
a rib structure attached to the back side of the mirror portion,
wherein the actuator connectors are mechanically decoupled from the base portion via decoupling points.

19. A projection exposure apparatus, comprising:
an illumination system configured to illuminate an object field in an object plane; and
a projection optical unit comprising a plurality of optical elements configured to image the illuminated object field into an image field,
wherein at least one of the optical elements comprises an optical element according to claim 1.

20. The projection exposure apparatus of claim 19, wherein the projection optical unit further comprises the actuators.
